(19) United States
(12) Patent Application Publication
(10) Pub. No.: US 2018/0342577 A1
(43) Pub. Date: Nov. 29, 2018

(54) SEMICONDUCTOR DEVICE AND METHOD OF MANUFACTURING THE SAME

(71) Applicant: Renesas Electronics Corporation, Tokyo (JP)

(72) Inventors: Hiroki FUJII, Hitachinaka-shi (JP); Takahiro MORI, Hitachinaka-shi (JP)

(73) Assignee: Renesas Electronics Corporation, Tokyo (JP)

(21) Appl. No.: 15/971,130

(22) Filed: May 4, 2018

(30) Foreign Application Priority Data
May 23, 2017 (JP) 2017-101603

(51) Int. Cl. H01L 29/06; H01L 29/66; H01L 29/423; H01L 29/08

(52) U.S. Cl. CPC H01L 29/0646; H01L 29/66681; H01L 29/42364; H01L 29/0878; H01L 29/0882; H01L 29/086; H01L 29/0865

(57) ABSTRACT

A first comb portion of an n-type well region and a second comb portion of a p⁻ drift region mesh with each other in plan view. A pn junction of the n-type well region and the p⁻ drift region thus has a zigzag shape in plan view. The pn junction formed of the n-type well region and the p⁻ drift region extends from a main surface toward a bottom surface of the isolation trench along a source-side wall surface of an isolation trench.

This nonprovisional application is based on Japanese Patent Application No. 2017-101603 filed on May 23, 2017 with the Japan Patent Office, the entire contents of which are hereby incorporated by reference.

### BACKGROUND OF THE INVENTION

### Field of the Invention

The present invention relates to a semiconductor device and a method of manufacturing the same.

### Description of the Background Art

For example, Japanese Patent Laying-Open No. 2015-162581 discloses a technique of reducing variations in the hot carriers of an LDMOS (Laterally Diffused Metal Oxide Semiconductor) transistor. In the publication, a recess is provided in STI (Shallow Trench Isolation) between a gate and a drain, and the recess is filled with a gate electrode. The publication describes an effect of reducing a gate current (Ig) that is an indicator of variations in hot carriers by about three digits using this structure.

The method of forming a superjunction structure in which n-layers and p-layers having a small width and a relatively high concentration are arranged alternately in a drift drain is sometimes used as the technique of reducing an on resistance of an LDMOS. For example, according to Japanese National Patent Publication No. 2004-508697, n-layers and p-layers are arranged alternately in a channel length direction. Further, according to Sameh, G. Nassif-Khalil and C. Andre T. Salama, “SJ/RESURF LDMOST”, IEEE Trans. Electron Devices, Vol. 51, pp. 1185-1191, 2004, n layers and p layers are arranged alternately in a channel width direction.

### SUMMARY OF THE INVENTION

In Japanese Patent Laying-Open No. 2015-162581, however, a step for one mask is required to provide a recess.

The superjunction structures described in Japanese National Patent Publication No. 2004-508697 and Japanese Patent Laying-Open No. 2015-162581 have high concentrations of both the n-layers and p-layers compared with typical structures. This can reduce an on resistance with a breakdown voltage maintained, whereas a field relaxing effect at an STI edge decreases. Further, in simultaneous production of an LDMOS transistor having no superjunction structure, a mask step needs to be added.

The other objects and new features will become apparent from the description of the present specification and the accompanying drawings.

In a semiconductor device according to one embodiment, a pn junction formed of a well region and a drift region extends from a main surface toward a bottom of an isolation trench along a lateral surface of the isolation trench on the side of a source region.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic plan view of a configuration of a semiconductor device in the form of a chip in a first embodiment;

FIG. 2 is a cross-sectional view of the configuration of the semiconductor device shown in FIG. 1;

FIG. 3 is a plan view of the configuration of the semiconductor device in the first embodiment;

FIG. 4 is a schematic cross-sectional view taken along line IV-IV of FIG. 3;

FIG. 5 is a schematic cross-sectional view taken along line V-V of FIG. 3;

FIG. 6 is a schematic perspective view showing the distribution of n-type well regions NWL and p⁻ drift regions DFT in the vicinity of an isolation trench of the semiconductor device shown in FIG. 3;

FIG. 7 is a schematic cross-sectional view taken along line VII-VII of FIG. 3;

FIGS. 8A and 8B are schematic cross-sectional views showing a first step of a method of manufacturing a semiconductor device in the first embodiment;

FIGS. 9A and 9B are schematic cross-sectional views showing a second step of the method of manufacturing a semiconductor device in the first embodiment;

FIGS. 10A and 10B are schematic cross-sectional views showing a third step of the method of manufacturing a semiconductor device in the first embodiment;

FIGS. 11A and 11B are schematic cross-sectional views showing a fourth step of the method of manufacturing a semiconductor device in the first embodiment;

FIGS. 12A and 12B are schematic cross-sectional views showing a fifth step of the method of manufacturing a semiconductor device in the first embodiment;

FIGS. 13A and 13B are schematic cross-sectional views showing a sixth step of the method of manufacturing a semiconductor device in the first embodiment;

FIG. 14 is a perspective view showing the state of a semiconductor device in the step shown in FIG. 10;

FIG. 15 shows the distribution of impact ionization rates in a comparative example;

FIG. 16 shows the distribution of impact ionization rates in the first embodiment;

FIG. 17 shows the dependence of gate current on gate voltage in each of the first embodiment and the comparative example;

FIG. 18 shows the distribution of electrostatic potentials along a dashed-dotted line D1-D2 of FIG. 7;

FIG. 19 is a cross-sectional view of a configuration of a semiconductor device in a second embodiment, which corresponds to a cross section taken along line V-V of FIG. 3;

FIG. 20 is a schematic perspective view showing the distribution of n-type well regions NWL and p⁻ drift regions DFT in the vicinity of an isolation trench of the semiconductor device shown in FIG. 19;

FIG. 21 shows the distribution of an n-type impurity concentration in a portion along each of a chain double-dashed line CS1 of FIG. 5 and a chain double-dashed line CS2 of FIG. 19;

FIG. 22 shows the distribution of an n-type impurity concentration in a portion along each of a chain double-dashed line CD1 of FIG. 5 and a chain double-dashed line CD2 of FIG. 19;

FIG. 23 is a cross-sectional view of a configuration of an nLDMOS transistor to which a configuration of this disclosure is applied, which corresponds to a cross section taken along line IV-IV of FIG. 3;

FIG. 24 is a cross-sectional view of a configuration of an nLDMOS transistor to which a configuration of this disclosure is applied, which corresponds to a cross section taken along line V-V of FIG. 3; and

FIG. 25 is a plan view of a configuration in which an n-type well region NWL surrounds a p⁻ drift region DFT.

### DESCRIPTION OF THE PREFERRED EMBODIMENTS

Hereinafter, embodiments will be described with reference to the drawings.

### First Embodiment

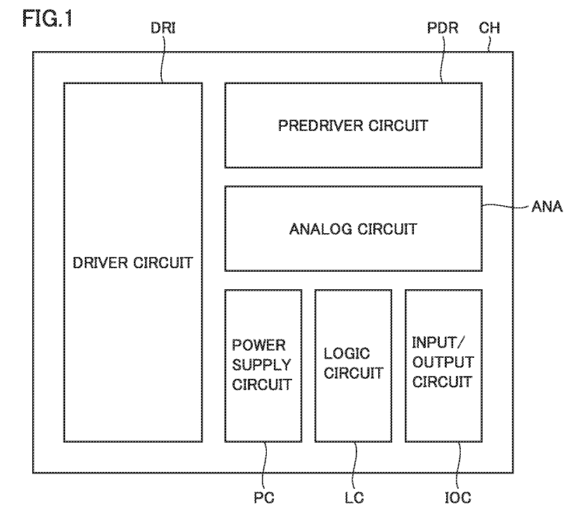

As shown in FIG. 1, a semiconductor device CH according to the present embodiment is in the form of, for example, a chip and includes a semiconductor substrate. Formation regions of a driver circuit DRI, a predriver circuit PDR, an analog circuit ANA, a power supply circuit PC, a logic circuit LC, an input/output circuit IOC, or the like are arranged in the surface of the semiconductor substrate.

The semiconductor device according to the present embodiment is not limited to a semiconductor chip and may be in the form of a wafer or a package sealed with sealing resin.

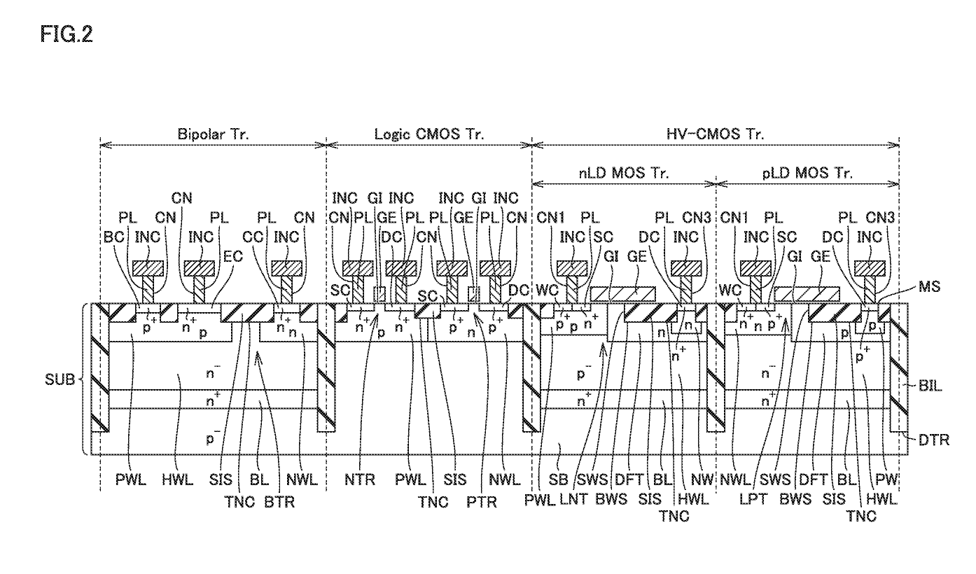

As shown in FIG. 2, the semiconductor device according to the present embodiment includes a high-breakdown-voltage CMOS (Complementary Metal Oxide Semiconductor) transistor, a logic CMOS transistor, and a bipolar transistor BTR.

The high-breakdown-voltage CMOS transistor includes an n-channel-type LD (Laterally Diffused) MOS transistor LNT and a p-channel-type LDMOS transistor LPT. The logic CMOS transistor includes an n-channel-type MOS transistor NTR and a p-channel-type MOS transistor PTR.

Hereinafter, the n-channel-type LDMOS transistor is referred to as an nLDMOS transistor, and the p-channel-type LDMOS transistor is referred to as a pLDMOS transistor. The n-channel-type MOS transistor is referred to as an nMOS transistor, and the p-channel-type MOS transistor is referred to as a pMOS transistor.

Each transistor is formed in a main surface MS of a semiconductor substrate SUB. The formation regions of the respective transistors are electrically isolated from each other by DTI (Deep Trench Isolation). The DTI includes a trench DTR formed in main surface MS of semiconductor substrate SUB and an insulating film BIL that fills trench DTR.

In the formation region of the logic CMOS transistor, a p-type well region PWL and an n-type well region NWL are arranged side by side in a p⁻ substrate region SB of semiconductor substrate SUB on the side of main surface MS. In p-type well region PWL, nMOS transistor NTR is arranged. In n-type well region NWL, pMOS transistor PTR is arranged.

The formation region of nMOS transistor NTR and the formation region of pMOS transistor PTR are electrically isolated from each other by STI (Shallow Trench Isolation). The STI includes an isolation trench TNC formed in main surface MS of semiconductor substrate SUB and an insulating isolation layer SIS that fills isolation trench TNC.

Isolation trench TNC of the STI is arranged to be shallower than trench DTR of the DTI from main surface MS. Isolation trench TNC of the STI is arranged to be shallower than p-type well region PWL and n-type well region NWL.

NMOS transistor NTR includes an n⁺ source region SC, an n⁺ drain region DC, a gate insulating layer GI, and a gate electrode GE. N⁺ source region SC and n⁺ drain region DC are spaced from each other in main surface MS of semiconductor substrate SUB. Gate electrode GE is arranged over main surface MS of semiconductor substrate SUB sandwiched between n⁺ source region SC and n⁺ drain region DC with gate insulating layer GI between main surface MS and gate electrode GE.

PMOS transistor PTR includes a p⁺ source region SC, a p⁺ drain region DC, a gate insulating layer GI, and a gate electrode GE. P⁺ source region SC and p⁺ drain region DC are spaced from each other in main surface MS of semiconductor substrate SUB. Gate electrode GE is arranged over main surface MS of semiconductor substrate SUB sandwiched between p⁺ source region SC and p⁺ drain region DC with gate insulating layer GI between main surface MS and gate electrode GE.

In the arrangement region of bioploar transistor BTR, an n⁺ buried region BL is arranged in p⁻ substrate region SB on the side of main surface MS. An n well region HWL is arranged in n⁺ buried region BL on the side of main surface MS. P-type well region PWL and n-type well region NWL are arranged in n⁻ well region HWL on the side of main surface MS. P-type well region PWL and n-type well region NWL are adjacent to each other with a part of n⁻ well region HWL sandwiched therebetween.

A p⁺ base region BC and an n⁺ emitter region EC are arranged in p-type well region PWL. An n⁺ collector region CC is arranged in n-type well region NWL. Bioploar transistor BTR is configured to include p⁺ base region BC, n⁺ emitter region EC, and n⁺ collector region CC.

STI is arranged between p⁺ base region BC and n⁺ emitter region EC and between n⁺ emitter region EC and n⁺ collector region CC. Consequently, p⁺ base region BC, n⁺ emitter region EC, and n⁺ collector region CC are electrically isolated from each another.

An interconnect layer INC is electrically connected to each impurity region (n⁺ source region SC, n⁺ drain region DC, p⁺ source region SC, p⁺ drain region DC, p⁺ base region BC, n⁺ emitter region EC, n⁺ collector region CC).

Specifically, an interlayer insulating layer (not shown) is arranged so as to cover main surface MS of semiconductor substrate SUB. Contact holes CN that reach the respective impurity regions are arranged in this interlayer insulating layer. A plug conductive layer PL is buried in contact hole CN. Interconnect layer INC is arranged on interlayer insulating layer so as to be in contact with plug conductive layer PL. Consequently, interconnect layer INC is electrically connected to each impurity region with plug conductive layer PL therebetween.

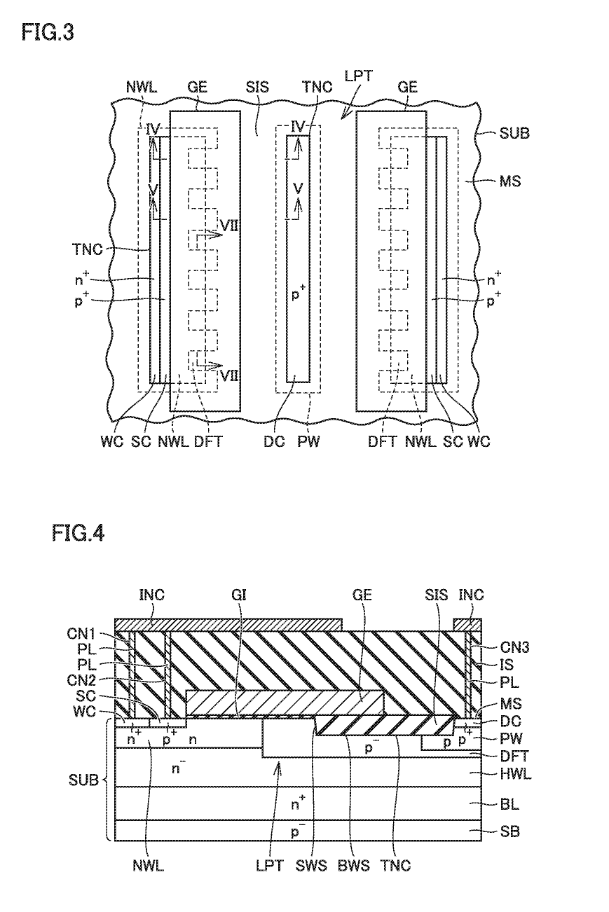

The pLDMOS transistor of the high-breakdown-voltage CMOS transistor shown in FIG. 2 will be described below with reference to FIGS. 3 to 7. Hereinafter, “plan view” refers to a point of view from a direction orthogonal to main surface MS of semiconductor substrate SUB.

As shown in FIG. 3, isolation trench TNC is formed in main surface MS of semiconductor substrate SUB in plan view. P⁺ drain region DC of a pLDMOS transistor LPT is arranged in one surface region of main surface MS which is surrounded by isolation trench TNC. A p⁻ drift region DFT, an n-type well region NWL, a p⁺ source region SC, and an n⁺ contact region WC of pLDMOS transistor LPT are arranged in another surface region of main surface MS which is surrounded by isolation trench TNC.

In plan view, n-type well region NWL has a first comb portion, and p⁻ drift region DFT has a second comb portion. In plan view, the first comb portion of n-type well region NWL and the second comb portion of p⁻ drift region DFT mesh with each other. In plan view, a pn junction of n-type well region NWL and p⁻ drift region DFT accordingly has a zigzag shape.

As shown in FIG. 4, n⁺ buried region BL is arranged in the arrangement region of pLDMOS transistor LPT on the side of main surface MS of p⁻ substrate region SB of semiconductor substrate SUB. N⁺ buried region BL forms a pn junction together with p⁻ substrate region SB. N⁻ well region HWL (impurity region) is arranged in n⁺ buried region BL on the side of main surface MS. N⁻ well region HWL is bonded with n⁺ buried region BL. N⁻ well region HWL has an n-type impurity concentration lower than the n-type impurity concentration of n⁺ buried region BL.

P⁻ drift region DFT and n-type well region NWL are arranged in n⁻ well region HWL on the side of main surface MS. In other words, n⁻ well region HWL is arranged opposite to main surface MS with respect to p⁻ drift region DFT and n-type well region NWL. P⁻ drift region DFT forms a pn junction together with n⁻ well region HWL. N-type well region NWL is bonded with n⁻ well region HWL. N⁻ well region HWL has an n-type impurity concentration lower than the n-type impurity concentration of n-type well region NWL.

P⁻ drift region DFT and n-type well region NWL are adjacent to each other so as to form a pn junction. In the cross section shown in FIG. 4, the pn junction formed of p⁻ drift region DFT and n-type well region NWL extends from main surface MS of semiconductor substrate SUB along the depth direction.

STI is arranged in main surface MS of semiconductor substrate SUB. This STI has isolation trench TNC and insulating isolation layer SIS. Isolation trench TNC is filled with insulating isolation layer SIS.

P⁺ source region SC and n⁺ contact region WC are arranged in main surface MS within n-type well region NWL. P⁺ source region SC and n⁺ contact region WC are adjacent to each other. P⁺ source region SC forms a pn junction together with each of n-type well region NWL and n⁺ contact region WC. N⁺ contact region WC has an n-type impurity concentration higher than the n-type impurity concentration of n-type well region NWL. N-type well region NWL is arranged in main surface MS between p⁺ source region SC and isolation trench TRC.

P⁻ drift region DFT has a portion arranged below isolation trench TNC. P⁻ drift region DFT is in contact with both a source-side wall surface SWS (lateral surface on the side of source region SC) and a bottom surface BWS of isolation trench TNC. The depth of p⁻ drift region DFT from main surface MS is greater than the depth of isolation trench TNC. P-type well region PW is arranged in p⁻ drift region DFT on the side of main surface MS. P-type well region PW is bonded with p⁻ drift region DFT.

P⁺ drain region DC is arranged in main surface MS of semiconductor substrate SUB. P⁺ drain region DC is adjacent to isolation trench TNC. P⁺ drain region DC sandwiches isolation trench TNC between p⁺ source region SC and itself.

P⁺ drain region DC is located in p-type well region PW on the side of main surface MS and is bonded with p-type well region PW. P⁺ drain region DC has a p-type impurity concentration higher than the p-type impurity concentration of p⁻ drift region DFT. P-type well region PW has a p-type impurity concentration higher than the p-type impurity concentration of p⁻ drift region DFT and also has a p-type impurity concentration lower than the p-type impurity concentration of p⁺ drain region DC.

Gate electrode GE is arranged over main surface MS sandwiched between p⁺ source region SC and p⁻ drift region DFT with gate insulating layer GI between main surface MS and gate electrode GE. Gate electrode GE faces main surface MS sandwiched between p⁺ source region SC and p⁻ drift region DFT while being insulated therefrom.

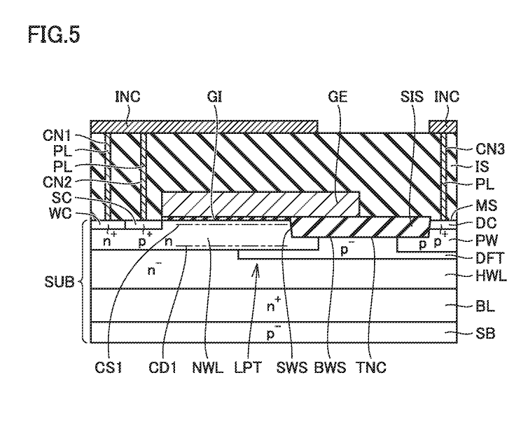

Gate electrode GE overlaps onto insulating isolation layer SIS of the STI. Gate electrode GE faces each of p⁻ drift region DFT and n-type well region NWL (FIG. 5) with insulating isolation layer SIS of the STI therebetween.

As shown in FIG. 5, in this cross section, n-type well region NWL is in contact with both source-side wall surface SWS (lateral surface on the side of source region SC) and bottom surface BWS of isolation trench TNC. P⁻ drift region DFT is in contact with bottom surface BWS of isolation trench TNC and is also in contact with the lower surface of n-type well region NWL. A pn junction of the upper surface of p⁻ drift region DFT and the lower surface of n-type well region NWL extends toward main surface MS.

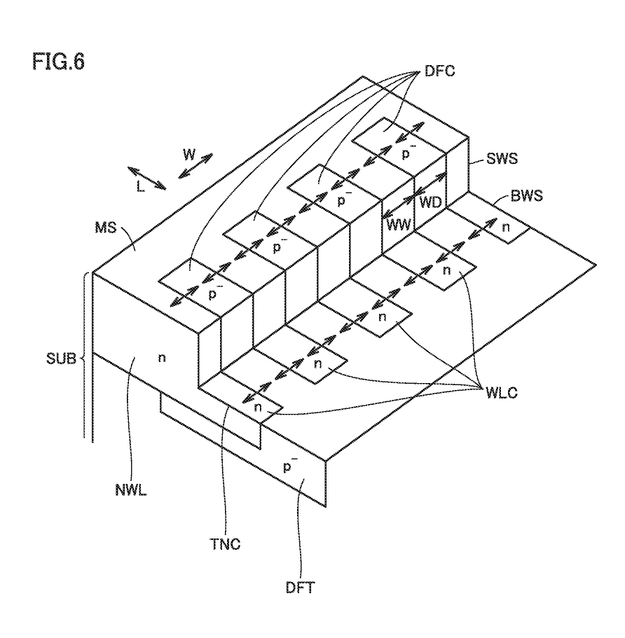

As shown in FIG. 6, n-type well region NWL has a plurality of well tooth portions WLC. Each one of the plurality of well tooth portions WLC forms a corresponding one of the teeth in the first comb portion of n-type well region NWL. P⁻ drift region DFT has a plurality of drift tooth portions DFC. Each one of the plurality of drift tooth portions DFC forms a corresponding one of the teeth in the second comb portion of p⁻ drift region DFT.

In plan view, the first comb portion of n-type well region NWL and the second comb portion of p⁻ drift region DFT mesh with each other. Specifically, the plurality of well tooth portions WLC forming the first comb portion and the plurality of drift tooth portions DFC forming the second comb portion are arranged alternately.

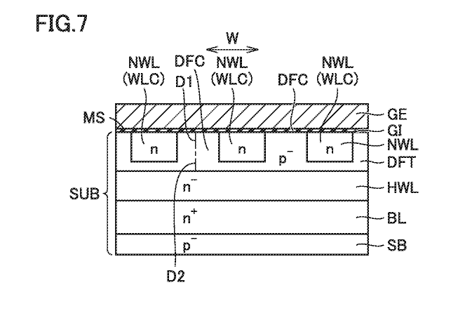

Consequently, as shown in FIGS. 6 and 7, the plurality of well tooth portions WLC and the plurality of drift tooth portions DFC are arranged alternately in a channel width direction W of pLDMOS transistor LPT in main surface MS.

As shown in FIG. 6, the plurality of well tooth portions WLC and the plurality of drift tooth portions DFC are arranged alternately along channel width direction W of pLDMOS transistor LPT also in each of source-side wall surface SWS and bottom surface BWS of isolation trench TNC.

A pn junction of well tooth portion WLC and drift tooth portion DFC extends along a channel length direction L of pLDMOS transistor LPT in plan view. The pn junction of well tooth portion WLC and drift tooth portion DFC extends along the channel direction from main surface MS through source-side wall surface SWS of isolation trench TNC to reach bottom surface BWS of isolation trench TNC. The pn junction formed of n-type well region NWL and p⁻ drift region DFT accordingly extends along source-side wall surface SWS of isolation trench TNC from main surface MS toward bottom surface BWS of isolation trench TNC.

Two well tooth portions WLC of the plurality of well tooth portions WLC sandwich one drift tooth portion DFC of the plurality of drift tooth portions DFC. The plurality of well tooth portions WLC and the plurality of drift tooth portions DFC are arranged alternately along channel width direction W of pLDMOS transistor LPT in source-side wall surface SWS of isolation trench TNC.

In source-side wall surface SWS of isolation trench TNC, a dimension (width) WW of each of the plurality of well tooth portions WLC in the direction along main surface MS is greater than a dimension (width) WD of each of the plurality of drift tooth portions DFC in the direction along main surface MS.

As shown in FIGS. 4 and 5, interlayer insulating layer IS is arranged on main surface MS of semiconductor substrate SUB so as to cover pLDMOS transistor LPT. Contact holes CN1, CN2, and CN3 that respectively reach n⁺ contact region WC, p⁺ source region SC, and p⁺ drain region DC are provided in interlayer insulating layer IS. Contact holes CN1 to CN3 are each filled with plug conductive layer PL. Interconnect layer INC is arranged on interlayer insulating layer IS so as to be in contact with plug conductive layer PL. Consequently, interconnect layer INC is electrically connected to each impurity region with plug conductive layer PL therebetween.

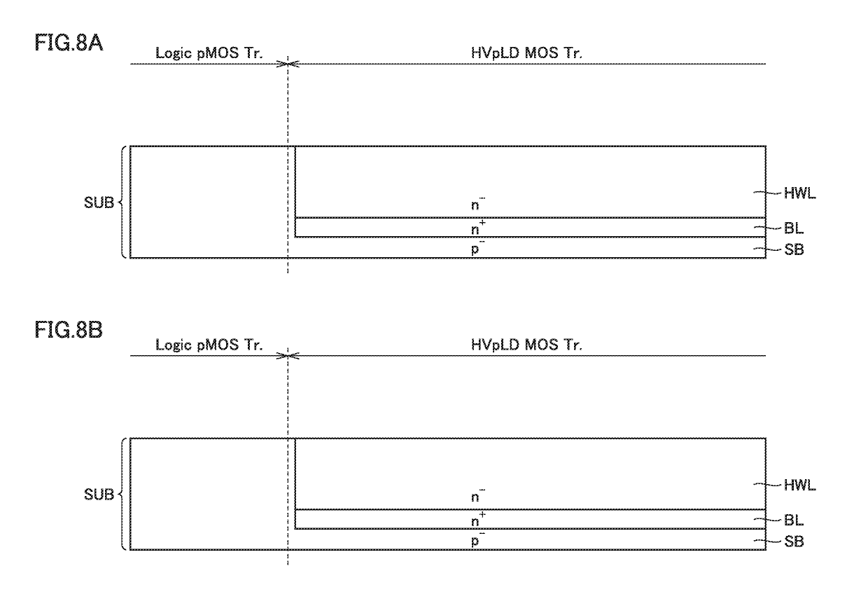

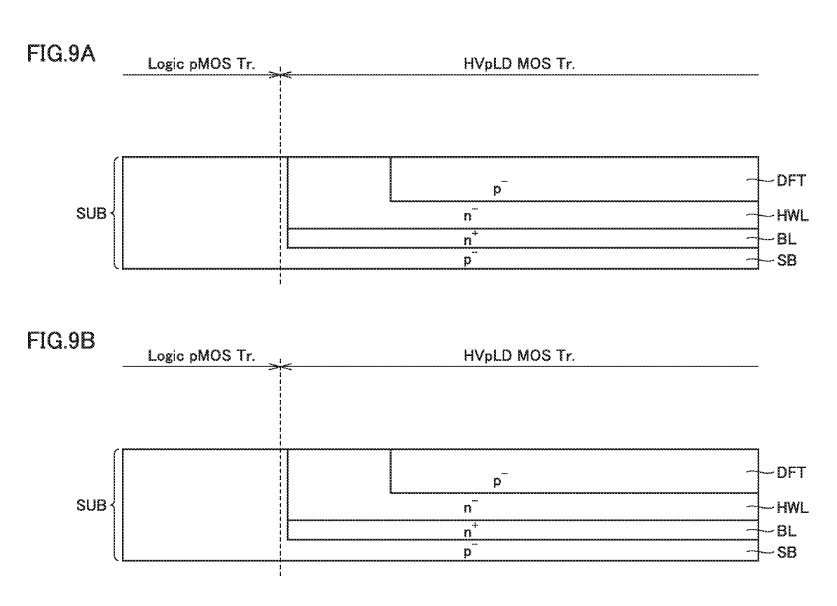

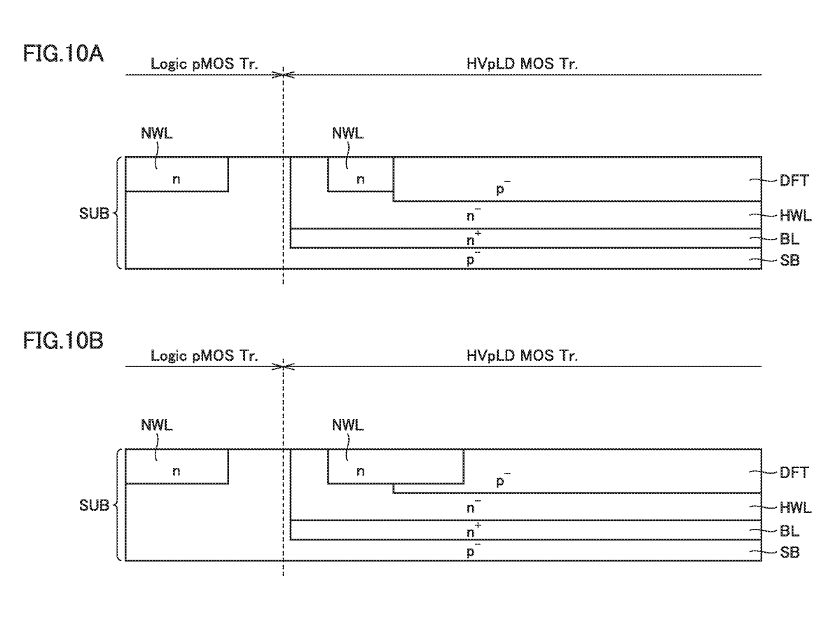

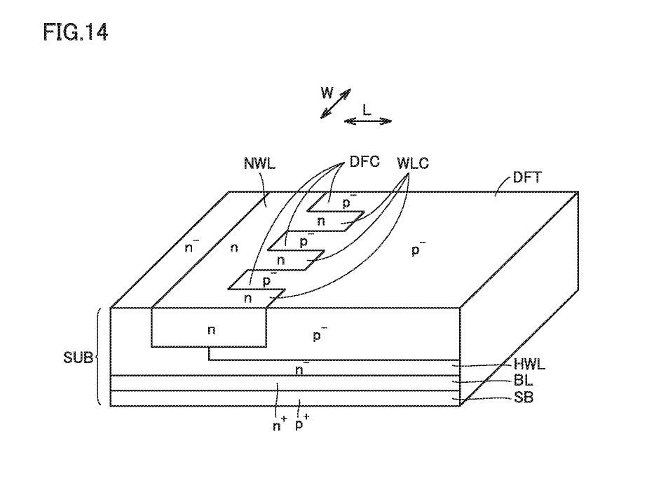

A method of manufacturing a semiconductor device according to the present embodiment will now be described with reference to FIGS. 4 to 6 and FIGS. 8A, 8B, 9A, 9B, 10A, 10B. 11A, 11B. 12A, 12B. 13A, 13B, and 14. FIGS. 8A, 9A. 10A. 11A. 12A, and 13A each correspond to a cross section taken along line IV-IV of FIG. 3. FIGS. 8B, 9B, 10B, 11B, 12B, and 13B each correspond to a cross section taken along line V-V of FIG. 3. Although p-type well region PW shown in FIG. 4 is omitted in FIGS. 8A to 13B, p-type well region PW may be provided. FIG. 14 is a perspective view showing the state of the formation region of the pLDMOS transistor in the step of FIG. 10.

As shown in FIGS. 8A and 8B, in the formation region of pLDMOS transistor LPT, n⁺ buried region BL is formed on p⁻ substrate region SB. N⁻ well region HWL is formed on n⁺ buried region BL.

As shown in FIGS. 9A and 9B, a first photoresist pattern (not shown) is formed on main surface MS of semiconductor substrate SUB by a typical photolithography process. P-type impurities are ion-implanted into main surface MS of semiconductor substrate SUB using this first photoresist pattern as a mask. Consequently, p⁻ drift region DFT is formed on n⁻ well region HWL. Subsequently, the first photoresist pattern is removed by, for example, ashing.

As shown in FIGS. 10A and 10B, a second photoresist pattern (not shown) is formed on main surface MS of semiconductor substrate SUB by a typical photolithography process. N-type impurities are ion-implanted into main surface MS of semiconductor substrate SUB using this second photoresist pattern as a mask. Consequently, n-type well region NWL is formed in main surface MS so as to form a pn junction together with p⁻ drift region DFT. Subsequently, the second photoresist pattern is removed by, for example, ashing.

In this state, in main surface MS, n-type well region NWL is formed to have the first comb portion, and p⁻ drift region DFT is formed to have the second comb portion, as shown in FIG. 14. N-type well region NWL is formed to have the plurality of well tooth portions WLC that serve as the teeth of the first comb portion. P⁻ drift region DFT is formed to have the plurality of drift tooth portions DFC that serve as the teeth of the second comb portion.

The first comb portion of n-type well region NWL and the second comb portion of p⁻ drift region DFT are formed so as to mesh with each other. Specifically, the plurality of well tooth portions WLC and the plurality of drift tooth portions DFC are formed in main surface MS so as to be alternately arranged along channel width direction W of pLDMOS transistor LPT. The pn junction of well tooth portion WLC and drift tooth portion DFC is formed so as to extend along channel length direction L of pLDMOS transistor LPT. The first comb portion of n-type well region NWL is formed to be shallower than p⁻ drift region DFT.

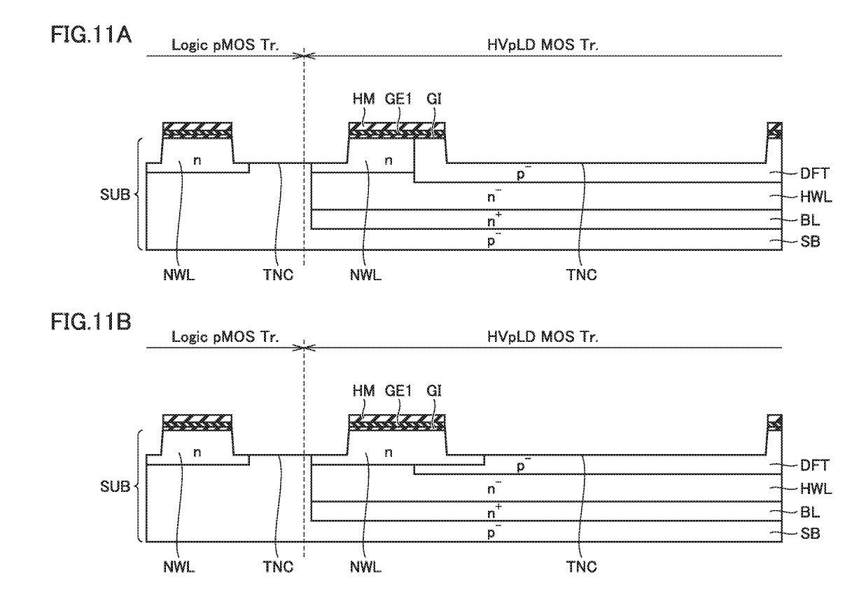

As shown in FIGS. 11A and 11B, gate insulating layer GI formed of, for example, silicon oxide film is formed on main surface MS of semiconductor substrate SUB. Gate insulating layer GI is formed having a film thickness of, for example, several micrometers to several tens of micrometers. On gate insulating layer GI, conductive film GE1 made of, for example, impurity-doped polycrystalline silicon (doped polysilicon) is formed. A hard mask layer HM formed of, for example, silicon nitride film is formed on conductive film GE1. Each of conductive film GE1 and hard mask layer HM is formed having a film thickness of, for example, several tens of nanometers.

Subsequently, hard mask layer HM is patterned by a typical photolithography process and a typical etching process. Conductive film GE1, gate insulating layer GI, and semiconductor substrate SUB are etched using the patterned hard mask layer HM as a mask. This etching forms isolation trench TNC in main surface MS of semiconductor substrate SUB.

As shown in FIG. 6, isolation trench TNC is formed having a depth smaller than the depths of n-type well region NWL and p⁻ drift region DFT. Isolation trench TNC is also formed such that the plurality of well tooth portions WLC and the plurality of drift tooth portions DFC are arranged alternately in source-side wall surface SWS of isolation trench TNC. Isolation trench TNC is also formed such that the plurality of well tooth portions WLC and the plurality of drift tooth portions DFC are arranged alternately in bottom surface BWS of isolation trench TNC.

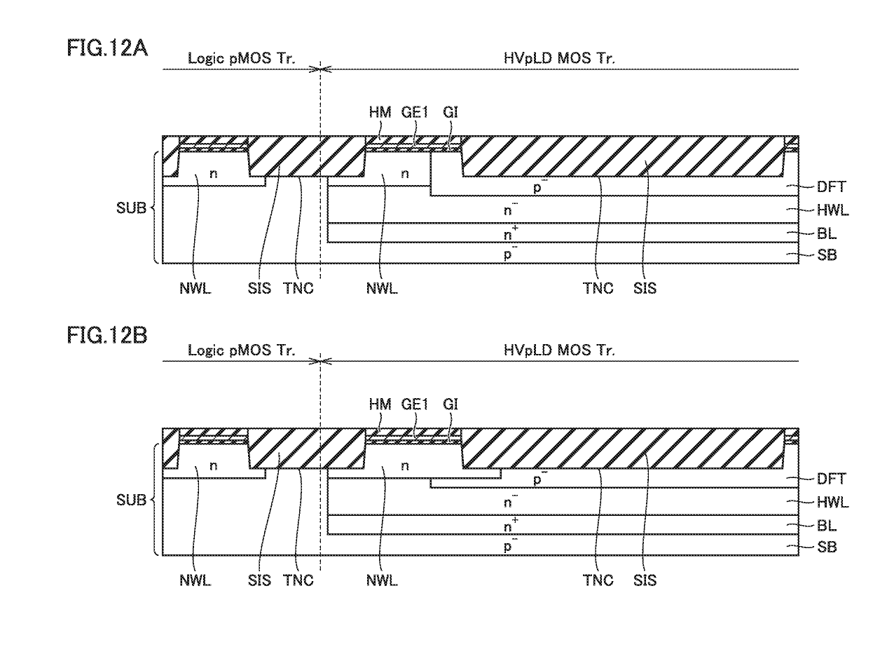

As shown in FIGS. 12A and 12B, insulating isolation layer SIS formed of, for example, silicon oxide film is formed so as to fill isolation trench TNC. In the formation of insulating isolation layer SIS, for example, an insulating layer is formed on the entire main surface of semiconductor substrate SUB so as to fill isolation trench TNC. Subsequently, the insulating layer is polished so as to expose the surface of hard mask layer HM by, for example, CMP (Chemical Mechanical Polishing). Consequently, insulating isolation layer SIS remains only in isolation trench TNC.

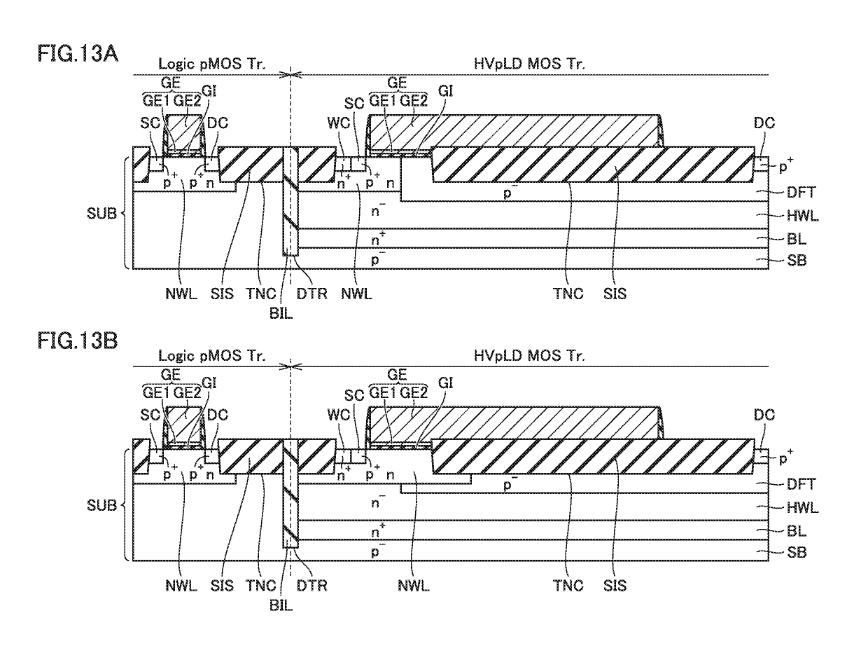

As shown in FIGS. 13A and 13B, a conductive film GE2 made of, for example, doped silicon is formed on the entire surface of main surface MS of semiconductor substrate SUB. Conductive film GE2 is formed having a film thickness of, for example, several tens of nanometers. Subsequently, conductive films GE2 and GE1 are patterned by a typical photolithography process and a typical etching process. Consequently, gate electrode GE formed of conductive films GE1 and GE2 is formed.

A sidewall-shaped lateral wall insulating layer is formed on the lateral wall of gate electrode GE. Subsequently, n-type impurities and p-type impurities are implanted into main surface MS of semiconductor substrate SUB by, for example, ion implantation. Consequently, p⁺ source region SC, p⁺ drain region DC, and n⁺ contact region WC are formed in main surface MS of semiconductor substrate SUB.

As shown in FIGS. 4 and 5, a semiconductor device according to the present embodiment is manufactured by the formation of interlayer insulating layer IS, plug conductive layer PL, interconnect layer INC, and the like.

The operation and effect of the present embodiment will now be described.

In the BiC-DMOS (Bipolar Complementary Metal Oxide Semiconductor) field, as shown in FIG. 2, an LDMOS transistor, a logic CMOS transistor, and a bioploar transistor are combined. Also in such a field, design scaling is being pursued. As a result, STI has been used in place of conventional LOCOS (LoCal Oxidation of Silicon).

In this case, STI is used also in the drift region of the LDMOS transistor. In the STI, a corner of the isolation trench has a sharp shape, thus allowing an electric field to easily concentrate on the corner of the isolation trench at the application of a high voltage to the drain. This electric field concentration easily leads to impact ionization at the edge of the STI. An electron-hole pair generated by impact ionization generates an interface state or is implanted into an oxide film due to scattering. As a result, large variations in hot carriers may occur remarkably. Particularly in a pLDMOS transistor, a breakdown occurs in a gate insulating layer due to the electron injection into the gate insulating layer.

Solving such a reliability-related problem is more important than reducing an on resistance, particularly in on-vehicle applications.

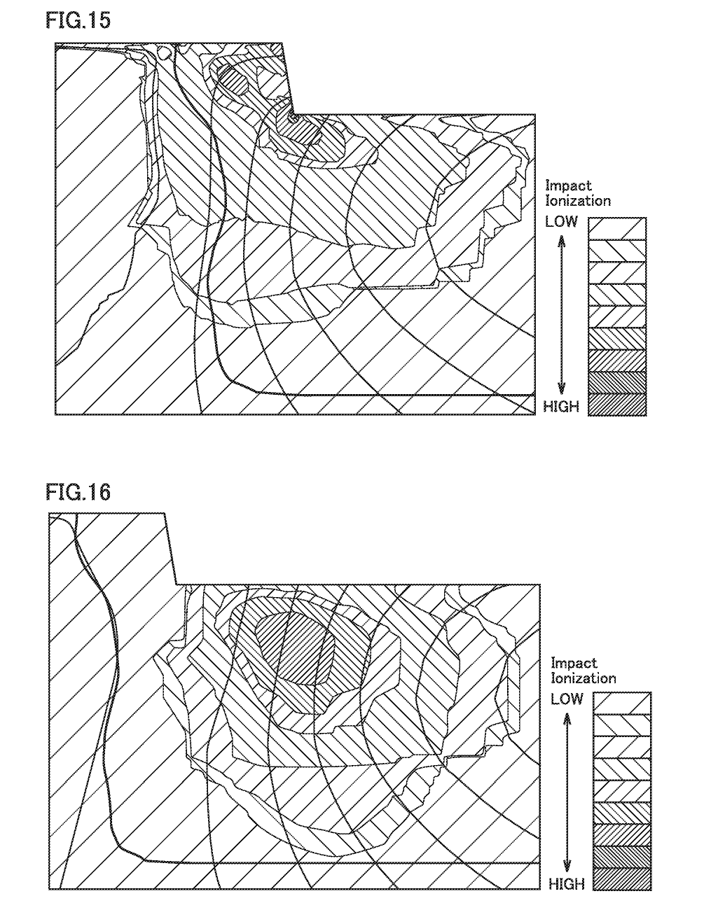

The inventors of the present invention therefore examined an effect of suppressing impact ionization by device simulation in the configuration of the present embodiment in FIGS. 3 to 5 and the configuration of the comparative example. The comparative example had a configuration in which each of n-type well region NWL and p⁻ drift region DFT is not formed in a comb shape in FIG. 3 and has a cross section shown in FIG. 4 in the channel width direction in its entirety. Simulation results are shown in FIGS. 15 and 16.

FIG. 15 shows the distribution of impact ionization rates of the semiconductor device in the comparative example, and FIG. 16 shows the distribution of impact ionization rates of the semiconductor device in the present embodiment. These results reveal that in the comparative example, the lower edge of the SIT on the side of the source region has a higher impact ionization rate as shown in FIG. 15. Contrastingly, in the present embodiment, the lower edge of the SIT on the side of the source region has an impact ionization rate lower than that of the comparative example as shown in FIG. 16.

These results are conceivably due to the following reason.

It is considered that in the present embodiment, impact ionization was successfully suppressed because n-type well regions NWL and p⁻ drift regions DFT are distributed alternately in source-side wall surface SWS of isolation trench TNC. In other words, a current flows through p⁻ drift region DFT during ON of pLDMOS transistor LPT. However, no current flows trough n-type well region NWL except for the portion inverted into a channel. Impact ionization occurs in the region where current flows. Thus, impact ionization occurs in p⁻ drift region DFT, whereas impact ionization does not occur in n-type well region NWL. Impact ionization thus does not occur in source-side wall surface SWS in which n-type well region NWL is arranged, so it is considered that impact ionization was successfully suppressed.

Considering the above, impact ionization can be suppressed more when width WD of drift tooth portion DFC in source-side wall surface SWS of isolation trench TNC shown in FIG. 6 is smaller than width WW of well tooth portion WLC.

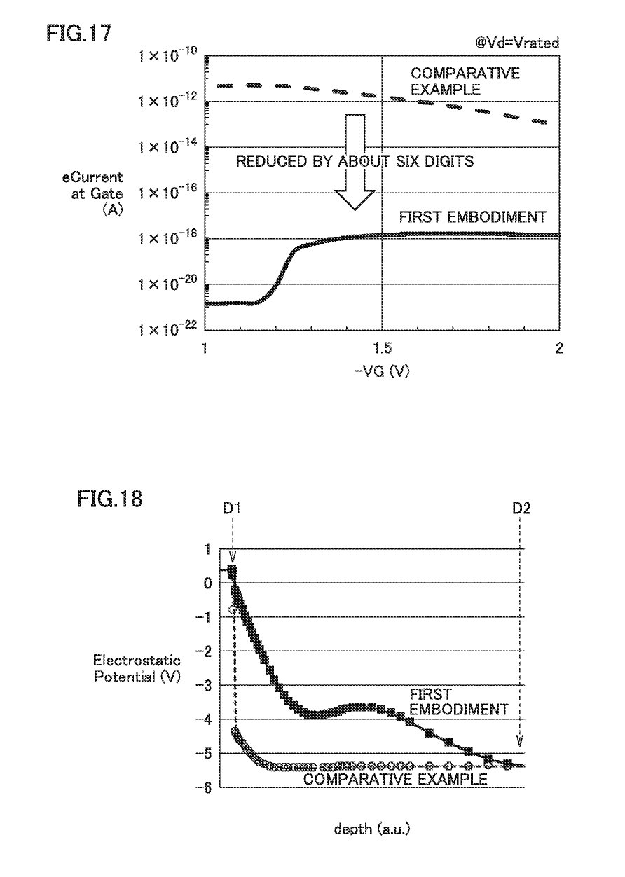

The inventors of the present invention examined the dependence of gate current on gate voltage. The results are shown in FIG. 17. FIG. 17 shows variations in the gate current obtained when the gate potential is changed with an electrostatic potential of −80 V being applied to the drain and the semiconductor substrate in each of the configuration of the present embodiment and the configuration of the comparative example. The results of FIG. 17 reveal that the gate current can be reduced by about six digits in the present embodiment compared with the comparative example.

Herein, the gate current refers to a current flowing between semiconductor substrate SUB and gate electrode GE with gate insulating layer GI or the like therebetween. A smaller gate current thus means a smaller amount of carriers injected into gate electrode GE from semiconductor substrate SUB. The above results of a reduced gate current thus reveal that the injection of hot carriers into gate electrode GE can be reduced more in the present embodiment than in the comparative example.

The inventors of the present invention also examined the electrostatic potential distribution along a dashed-dotted line D1-D2 of FIG. 7. The results are shown in FIG. 18. In the measurements of the electrostatic potential distribution, −5 V was applied to p⁻ drift region DFT with n-type well region NWL set to a grounding potential and the gate electrode set to 0 V in FIG. 7.

FIG. 18 shows electrostatic potential distribution along dashed-dotted line D1-D2 of FIG. 7. The results of FIG. 18 reveal that the electrostatic potential has a lower absolute value in the present embodiment than in the comparative example and that an electric field is mitigated in the present embodiment.

At the application of the above electrostatic potential in FIG. 7, a depletion layer extends in p⁻ drift region DFT sandwiched between n-type well regions NWL, from a pn junction formed of n-type well region NWL on either side and p⁻ drift region DFT. This facilitates the depletion of p⁻ drift region DFT at the application of reverse bias, and accordingly, an electric field is conceivably mitigated more in the present embodiment than in the comparative example.

The study above reveals that in the present embodiment, a pn junction formed of n-type well region NWL and p⁻ drift region DFT extends along source-side wall surface SWS of isolation trench TCN from main surface MS toward bottom surface BWS of isolation trench TNC. Consequently, not only p⁻ drift region DFT but also n-type well region NWL is located in source-side wall surface SWS of isolation trench TNC. Impact ionization does not occur within n-type well region NWL because no current flows through n-type well region NWL during ON of pLDMOS transistor LPT. Impact ionization is thus suppressed due to the distribution of both n-type well region NWL and p⁻ drift region DFT in source-side wall surface SWS of isolation trench TNC.

In the present embodiment, the pn junction formed of n-type well region NWL and p⁻ drift region DFT extends along source-side wall surface SWS of isolation trench TCN from main surface MS toward bottom surface BWS of isolation trench TNC. Such extension of the pn junction in the depth direction allows a depletion layer to extend in the direction along main surface MS (laterally) as indicated by the arrows of FIG. 6, similarly to a superjunction. This facilitates the depletion of p⁻ drift region DFT, thus improving a breakdown voltage during OFF.

It suffices that a photomask for forming n-type well region NWL is changed in the step shown in FIG. 10 in order to obtain the structure above. An additional manufacturing step is thus not required in the present embodiment, differently from the case of manufacturing the configuration of the comparative example. Also, a recess formation step is not additionally required in the present embodiment because there is also no need to provide a recess in an insulating isolation layer within an isolation trench as described in Japanese Patent Laying-Open No. 2015-162581.

The present embodiment above can suppress the injection of hot carriers into a gate insulating layer in a simple manufacturing step and also improve a breakdown voltage during OFF.

### Second Embodiment

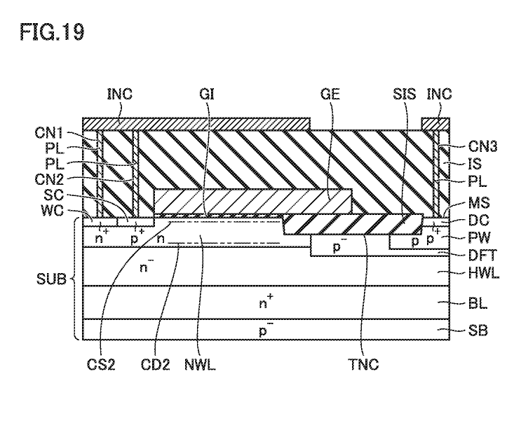

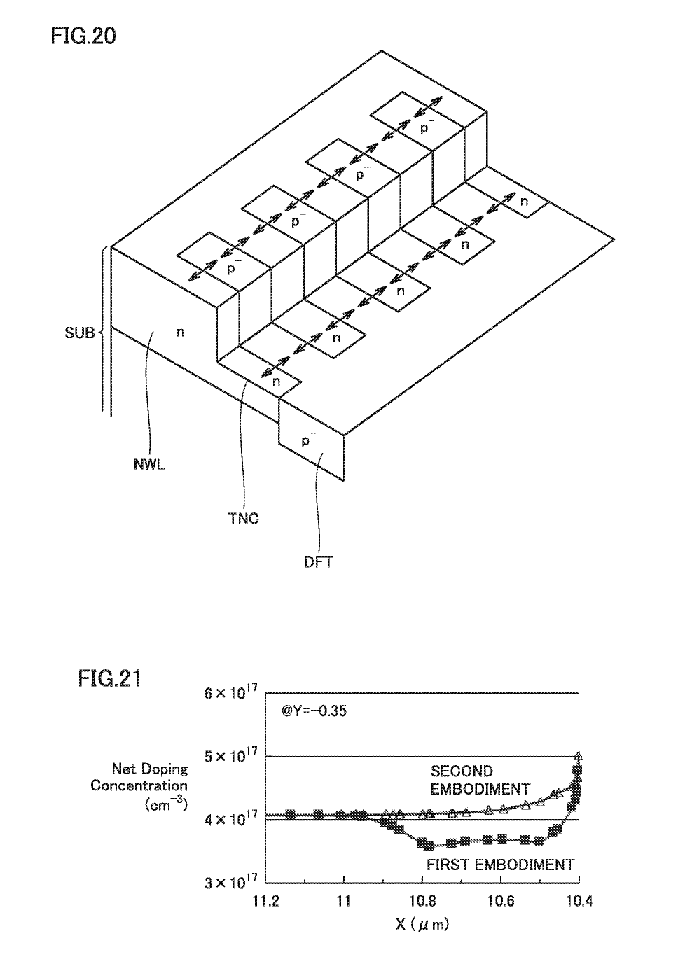

As shown in FIGS. 19 and 20, the configuration of the present embodiment differs from the configuration of the first embodiment in the configurations of p⁻ drift region DFT and n-type well region NWL.

In the present embodiment, p⁻ drift region DFT is not in contact with the lower surface of n-type well region NWL. The lower surface of n-type well region NWL is in contact with n⁻ well region HWL.

Specifically, in the first embodiment, p⁻ drift region DFT extends beyond source-side wall surface SWS of isolation trench TNC toward p⁺ source region SC as shown in FIG. 5. Contrastingly, in the present embodiment, p⁻ drift region DFT does not extend beyond source-side wall surface SWS toward p⁺ source region SC.

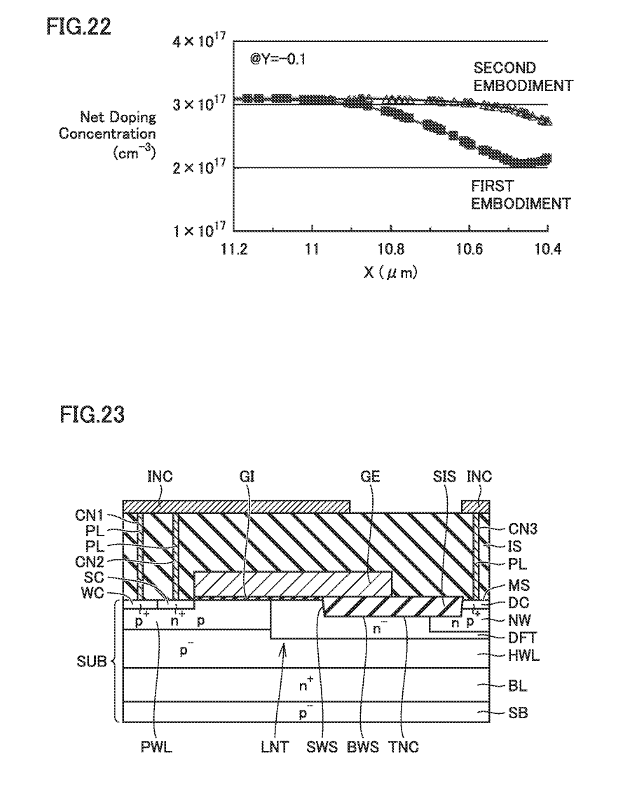

As shown in FIGS. 21 and 22, the net doping concentration of n-type impurity is thus higher on the side of p⁺ source region SC from source-side wall surface SWS of isolation trench TNC in the present embodiment than in the first embodiment.

The configurations of the present embodiment except for those described above are substantially identical to the configurations of the first embodiment, and thus, the same components as the components of the first embodiment will be denoted by the same reference signs, and their description will not be repeated.

The net doping concentration of n-type impurity is higher on the side of p⁺ source region SC from source-side wall surface SWS of isolation trench TNC in the present embodiment than in the first embodiment. This facilitates depletion, that is, increasing RESURF (REduced SURface Field) effects.

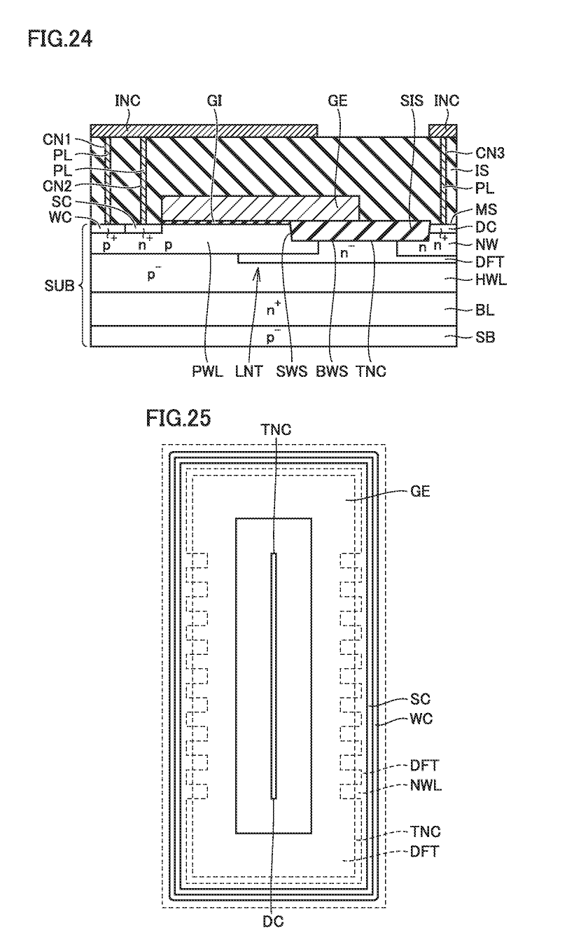

Although each of the first and second embodiments has described a pLDMOS transistor LPT, the description of this disclosure is also applicable to an nLDMOS transistor LNT, as shown in FIGS. 23 and 24. In this configuration, each of p-type well region PWL and n⁻ drift region DFT is formed in a comb shape in plan view, and the first comb portion of p-type well region PWL and the second comb portion of n drift region DFT mesh with each other.

Although the embodiments above have described the configuration in which n-type well regions NWL are provided side by side with p⁻ drift regions DFT in plan view as shown in FIG. 3, n-type well region NWL may surround p⁻ drift region DFT in plan view as shown in FIG. 25.

In this configuration, n-type well region NWL surrounds p⁻ drift region DFT in plan view, thus improving current driving ability during ON.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
a semiconductor substrate having a main surface, the main surface having an isolation trench;
a source region of first conductivity type which is disposed in the main surface of the semiconductor substrate;
a drain region of first conductivity type which is disposed in the main surface and sandwiches the isolation trench between the source region and the drain region;
a drift region of first conductivity type which is disposed below the isolation trench and has an impurity concentration lower than an impurity concentration of the drain region; and
a well region of second conductivity type which is disposed in the main surface between the source region and the isolation trench and forms a pn junction together with the drift region,
the pn junction formed of the well region and the drift region extending from the main surface toward a bottom surface of the isolation trench along a lateral surface of the isolation trench on a side of the source region.

2. The semiconductor device according to claim 1, wherein
the well region has a plurality of well tooth portions forming a first comb portion,
the drift region has a plurality of drift tooth portions forming a second comb portion,
two well tooth portions of the plurality of well tooth portions sandwich one drift tooth portion of the plurality of drift tooth portions, and
a pn junction of each of the plurality of well tooth portions and each of the plurality of drift tooth portions extends from the main surface toward the bottom surface of the isolation trench along the lateral surface of the isolation trench on the side of the source region.

3. The semiconductor device according to claim 2, wherein the plurality of well tooth portions and the plurality of drift tooth portions are arranged alternately in the lateral surface of the isolation trench on the side of the source region.

4. The semiconductor device according to claim 2, wherein in the lateral surface of the isolation trench on the side of the source region, a dimension of each of the plurality of well tooth portions along the main surface is greater than a dimension of each of the plurality of drift tooth portions along the main surface.

5. The semiconductor device according to claim 2, wherein a lower surface of the well region is in contact with the drift region.

6. The semiconductor device according to claim 2, further comprising an impurity region of second conductivity type which is disposed opposite to the main surface with respect to the well region and the drift region,
wherein a lower surface of the well region is not in contact with the drift region and is in contact with the impurity region.

7. The semiconductor device according to claim 1, wherein a depth of the drift region from the main surface is greater than a depth of the isolation trench.

8. The semiconductor device according to claim 1, wherein the well region surrounds the drift region in plan view.

9. The semiconductor device according to claim 1, further comprising:
an insulating isolation layer buried in the isolation trench; and
a gate electrode formed on the main surface so as to face the well region while being insulating therefrom and to extend on the insulating isolation layer.

10. A method of manufacturing a semiconductor device, comprising:
forming a drift region of first conductivity type and a well region of second conductivity type in a main surface of a semiconductor substrate, the drift region and the well region forming a pn junction;
forming an isolation trench in the main surface of the semiconductor substrate; and
forming a source region of first conductivity type and a drain region of first conductivity type in the main surface, the source region sandwiching the well region between the isolation trench and the source region and forming a pn junction together with the well region, the drain region sandwiching the isolation trench between the source region and the drain region and having an impurity concentration higher than an impurity concentration of the drift region,
the isolation trench being formed such that the pn junction formed of the well region and the drift region extends from the main surface toward a bottom surface of the isolation trench along a lateral surface of the isolation trench on a side of the source region.
